(19) United States
(12) Patent Application Publication
(10) Pub. No.: US 2024/0202378 A1
(43) Pub. Date: Jun. 20, 2024

(54) METHOD FOR IDENTIFYING REPRESENTATIVES FOR ENGINEERING DESIGN CONCEPTS

(71) Applicant: Honda Research Institute Europe GmbH, Offenbach/Main (DE)

(72) Inventors: Felix Lanfermann, Offenbach (DE); Patricia Wollstadt, Offenbach (DE)

(73) Assignee: Honda Research Institute Europe GmbH, Offenbach/Main (DE)

(21) Appl. No.: 18/079,818

(22) Filed: Dec. 12, 2022

(51) Int. Cl. G06F 30/13; G06F 30/33

(52) U.S. Cl. CPC G06F 30/13; G06F 30/33

(57) ABSTRACT

The present disclosure relates to a computer-implemented method for performing a design process by processing design data of a physical object. The method includes acquiring a dataset including design data samples of design data, determining at least one design concept including design data samples from the acquired dataset based on at least a similarity of feature values of design features, calculating a local similarity measure between at least two description spaces for each design data sample included in the determined design concept, selecting a number of design data samples based on the calculated local similarity measure as most representative designs and least representative designs, outputting the selected most representative design to an engineering process for further processing or deleting the least representative design from the design data samples of the respective design concept, and processing at least one of the most representative design data samples in the engineering process.

### TECHNICAL FIELD OF THE DISCLOSURE

The disclosure relates to the general field of engineering and design processes and representative designs or archetypes for engineering design concepts. In particular, the field of engineering design optimization, evaluating of engineering design concepts and data mining is concerned. A method for automatic design concept definition and archetype selection for large sets of design data, which respect multiple description spaces, is proposed.

### BACKGROUND

In the field of engineering design processes, regularly a plurality of differing design candidates is created. The engineer subsequently analyses the created designs according to their specific characteristics and based on predefined design criteria. The design candidates may be classified and characterized based on their properties represented by features (design parameters, performance values, geometric features, and others). The features can include, for example, statistical or geometrical parameters derived from the design candidates. The performance values may include performance criteria of different technical disciplines under different environmental conditions.

The complete set of features describing a design candidate (or data sample) can be grouped into categories of features, sometimes called feature types. Each category represents characteristics of the design in one particular semantic context. Subsequently, a group of features, which share a common semantic meaning, in particular, which belong to the same feature category is referenced as a description space. For example, the combination of all features that represent the performance of the design candidates in a certain discipline for a set of specific environmental conditions may be denoted as one description space.

Design concepts comprise design data samples that are similar with respect to their feature values in each respective description space. Each design concept consists of design data samples, which belong to the same group in each description space simultaneously. For example, a design concept may contain design data samples that are similar with respect to all their design parameter values, their geometrical feature values, their performance values for different environmental conditions.

There currently exist optimization methods that enable to find independent solutions of high quality to design problems by considering two different description spaces. A single design criterion is applied to one description space and then optimized. However, a relation of the design data samples representing design solutions in the two different description spaces is not provided.

Analyzing large datasets of design data, comprising a plurality of design data samples (design samples), identifying, and assessing meaningful design concepts based on an arbitrary number of description spaces and previously defined characteristics and preferences set by the design engineer are a complex undertaking requiring large computational resources.

In the engineering design domain, a central task is identifying design concepts in order to identify groups of engineering designs that share similar characteristics, typically in terms of their specification, but also in terms of their performance or in terms of other types of descriptions, such as an operation mode under which a physical object is operating in the environment. When identifying design concepts, it is of importance that an identified group of designs is similar with respect to all describing features of those designs (design samples, design instances) forming part of the group of designs. The similarity with respect to all describing features of the designs forming part of the group of designs is has to be preserved when considering a subset of features of the designs of the group of designs in isolation. For example, designs samples included in a design concept should be highly similar with respect to all characteristics, but the designs samples of the design concept should also be similar in terms of only their specification or in terms of only their performance.

Once design concepts are identified, a next step is to identify archetype designs (archetypes or representative designs, representative design samples). Archetypes are representative instances of designs of a design concept and are useful, for example, as starting points for further optimization steps for optimizing a design concept for determining an optimized design.

Identifying design concepts may be viewed as a clustering of design concepts, or assigning designs to clusters with the following three constraints:
the generated clusters do not overlap. This is achieved by not assigning all instances of the designs into the generated clusters,
the design samples within a cluster have a high similarity with respect to all their features, and
the cluster assignment persists between all considered spaces: the joint space of all features of a plurality of features, and all relevant subspaces of at least one of the plurality of features. This means that designs, which are assigned to a same cluster in the joint space, are also assigned to the same cluster in all subspaces.

A vector comprising its characterizations in all description spaces, e.g., the design parameters along with the corresponding performance values, represents a design. A design concept amounts to a set of corresponding clusters, one in each description space. Considering the clustering of the space of complete design vectors, the clustering must be preserved in all subspaces defined by the individual description spaces, i.e., several specific projections of the full space. Technically, design concept identification can be viewed as a type of clustering problem as discussed in “an effective measure to identify meaningful concepts in engineering design optimization” by Felix Lanfermann et al, IEEE symposium series on computational intelligence SSCI, 2020.

One advantageous method for identifying design concepts is discussed hereinafter. The present proposal also considers an identification of representative designs after the design concepts were identified.

Methods for the identification of representative design for design concepts were discussed previously, however, all discussed methods involve elements from traditional clustering algorithms and are in particular not targeted at the special case of identifying design concepts. In the following, advantages of the proposed method for determining archetype designs for design concepts in comparison to known approaches to identify representative designs are presented.

Existing methods from clustering analysis for determining representative designs for clusters of designs (design concepts) include
computing a geometric mean with respect to all features or a subset/type of features of the design data samples of a concept design;
performing a random selection of a design sample of the plurality of design samples included in a design concept;
determining the representative design by selecting a design sample based on a highest density in a feature space of the plurality of design samples of the design concept;
determining the representative design by selecting a design sample based on a highest distance to in a feature space of the plurality of design samples of the design concept to other clusters of designs.

None of these known approaches take into account the specific constraints on concept identification solutions, in particular, none of the methods considers the similarity or correlation between description spaces.

The technical task is to identify engineering design instances that are representatives of a design concept. Representatives (representative designs) are needed as starting points of a subsequent optimizations of designs in order to achieve a further improved performance of the designs or in order to adjust specifications of the designs.

### SUMMARY

A computer-implemented method for performing a design process by processing design data of a physical object provides an advantageous solution. The method comprises steps of:
acquiring a dataset D including a plurality of design data samples of design data, each design data sample xᵢ representing one design variation of the physical object and comprising a plurality of design features f₁, . . . , f_{N}_{_{F}}. Each design feature fᵢ is included in at least one of a plurality of description spaces;
determining at least one design concept including a plurality of design data samples x₁, . . . , x_{N}_{_{D}} from the acquired a dataset D based on at least a similarity of feature values of the design features f₁, . . . , f_{N}_{_{F}}, wherein each design data sample x₁, . . . , x_{N}_{_{D}} comprises design features in at least two of the description spaces;
calculating a local similarity measure between the at least two description spaces for each design data sample x₁, . . . , x_{N}_{_{D}} included in the determined at least one design concept;
selecting a number of design data samples x₁, . . . , x_{N}_{_{D}} based on the calculated local similarity measure from the plurality of design data samples x₁, . . . , x_{N}_{_{D}} included in the determined at least one design concept as at least one of most representative designs and least representative designs; and
outputting the selected most representative design(s) to an engineering process for further processing; or
deleting the least representative design(s) from the design data samples x₁, . . . , x_{N}_{_{D}} of the respective design concept; and
processing at least one of the most representative design data samples of the at least one design concept in the engineering process.

### BRIEF DESCRIPTION OF THE DRAWINGS

The above-described aspects of the present disclosure will be explained in the following description of specific embodiments in relation to the enclosed drawings.

FIG. 1 illustrates an example of a two-dimensional description space of a plurality of design data samples and a plurality of design concepts identified in the description space.

FIG. 2 illustrates an example of a two-dimensional description space with three design concepts identified in the description space and representative designs for each design concept.

FIG. 3 depicts a simplified flowchart, which depicts method steps of an embodiment.

FIG. 4 illustrates a dataset D including multiple design data samples x₁, x₂, . . . , x_{N}_{_{D}}, the design data samples including features f₁, f₂, . . . , f_{N}_{_{F}} in plural description spaces.

FIG. 5 illustrates generation of a dataset using free-form-deformation (FFD) in the airfoil design implementation of an embodiment.

FIG. 6 illustrates terminology of the method in an application to an airfoil design dataset.

FIG. 7 shows a normalized dataset in five description spaces (parameter space, geometric feature space, objective space 1, objective space 2 and objective space 3) in the airfoil design implementation of the method.

FIG. 8 depicts a result of the concept determination process in the airfoil design implementation an embodiment.

FIG. 9 depicts an evaluation of the result of the concept identification process in the airfoil design implementation of an embodiment.

FIG. 10 illustrates a selection of representative design data samples of the identified design concepts in the airfoil design implementation of an embodiment.

FIG. 11 shows a simplified flowchart, which depicts method steps implementing an embodiment.

In the figures, same reference signs denote same or corresponding elements. The discussion of embodiments dispenses with discussing same reference signs indifferent figures wherever deemed possible without adversely affecting comprehensibility for sake of a concise description.

### DETAILED DESCRIPTION

The method generally uses a local similarity measure that quantifies a similarity between relevant description spaces for all design data samples, (design samples, designs) assigned to design concepts (concepts). Design data samples for specific designs of the physical object are selected as representative design (or: archetype designs, archetypes) for a design concept for which the determined similarity is most pronounced.

The method according to the first aspect proposes a novel method for identifying representative designs in design concepts including a plurality of design data samples. In particular, the method achieves identifying at least one representative design for a design concept using the local mutual information (LMI), which is a measure of similarity between relevant description spaces (subspaces). Using the LMI enables to identify instances of the plurality of designs samples as archetype designs, for which one description space is highly predictive or highly informative about the feature values in another description space. In other words, representative designs identified using the LMI are highly representative with respect to the similarity between description spaces. The representative designs identified by means of calculating and evaluating the LMI are those, for which a correlation between description spaces is at maximum. This property is desirable, for example, to identify those designs samples, for which small changes of design specifications in the specification description space have a high probability to lead to small changes in design performance in the performance description space.

None of the known approaches takes into account the specific constraints on concept identification, and, in particular, none of the methods considers the similarity or correlation between different description spaces. The method according to the first aspect achieves this contrary to the known approaches.

The method according to the first aspect identifies representative designs with respect to the specific constraints and goals of design concept identification. Concept identification aims at identifying design concepts such that instances of designs (design samples) included in the same design concept have a high similarity between relevant description spaces of the space of feature values of the designs. For example, a design concept should show high similarity for all design samples included in the design concept with respect to specifications and with respect to performance simultaneously. A consequence of the constraint of high similarity being simultaneously valid in all relevant description spaces is that there is also a high correlation between the description spaces. For example, there will exist a high correlation between specifications and performances for all design samples included in a design concept provided as solution of the step of identifying design concepts in a dataset of a plurality of designs.

The method according to the first aspect uses the measure of local similarity to identify design samples in the acquired dataset, for which the similarity is most pronounced. In other words, the identified representative design samples are characteristic with respect to the similarity or correlation between description spaces, which are subspaces of the space of designs of the design concept. This property of identified representative designs is advantageous, for example, to identify a particular specification for which, given the acquired dataset, a probability of finding a specific performance is at maximum. This property may be exploited in further design processing steps, as there exists a high probability that small changes in the specifications of the representative design lead to corresponding small changes in the performance of the representative design.

An advantageous field of applying the method according to the first aspect is engineering design. Relevant description spaces may include design specifications, design performance, and an operation mode of the design, for example. Initially, design concepts are identified in the acquired dataset and for all design data samples in the identified design concepts, the LMI is estimated, in particular computed. The designs with a highest LMI within a design concept are identified as representative design data samples for the respective design concept.

For these representative designs, when varying the specification of the archetype designs, a probability of finding designs samples with a similar performance is highest amongst all design data samples of the plurality of designs samples of the design concept. This characteristic is of importance when developing variants of a design, while simultaneously preserving desired performance values.

Local similarity describes how informative a value of a design data sample in one description space is with respect to a value of the same design sample in another description space. It describes how predictable the value in one description space is from the value in another description space. An implementation of a similarity measure is the mutual information MI. In particular, a local mutual information may be used to implement the local similarity measure, e.g., a sample-wise computed local mutual information (LMI). The LMI quantifies how the probability of observing outcome x changes when observing outcome y, compared to the prior probability of observing outcome x.

High local mutual information LMI identifies those design data samples of design concepts, for which one value is highly informative or predictive of the second value. On the other hand, low or even negative local mutual information identifies those design data samples where the value of the design concept in one description space is non-informative or even mis-informative about the value of the design concept in another description space.

The method according to the first aspect uses the LMI to identify those design data samples, for which the similarity of description spaces is most pronounced, corresponding to those design data samples for which the LMI is the highest. The method according to the first aspect defines such design data samples with a high LMI as representative designs (or: archetypes, archetype designs), denoting instances in the acquired design data that are highly representative of a design concept.

Furthermore, the method according to the first aspect may use the LMI for identifying novel designs as design data samples for which the LMI is low. In particular, the method according to the first aspect may use the LMI for identifying novel design data samples in a design concept as designs for which the LMI is the lowest, or even negative.

The computer-implemented method may include a step of determining relevant description spaces of the plurality of design data samples x₁, . . . , x_{N}_{_{D}} of the at least one design concept. The method proceeds with calculating the local similarity measure as a correlation between the design data samples x₁, . . . , x_{N}_{_{D}} in different description spaces of the determined relevant description spaces of the plurality of design data samples of the at least one design concept.

In the computer-implemented method according to an embodiment, the at least two description spaces include at least two of the description space of design specification parameters, geometrical features of the design, design performance parameters of at least one engineering discipline for one set of operation criteria, and an operation mode of the design.

In the computer-implemented method according to an embodiment, calculating the local similarity measure includes calculating a local mutual information measure defined by

$$i ( x ; y ) = log \frac{p ( x \vert y )}{p ( x )} ; \qquad ( 1 )$$

with the local similarity measure i(x; y), x and y are design data of the design data sample in the respective description spaces and p(x) defines a probability of occurrence of the characteristic data sample x in the first description space, and p (x|y) defines a probability of occurrence of the design data sample x in the first description space when observing the design data sample y in the second description space. Probabilities p (x) and p (x|y) are estimated from vectors X, Y of design samples x₁, . . . , x_{N}_{_{D}} in the respective subspaces of the design data sample.

The computer-implemented method may comprise in the step of processing the most representative design data samples x₁, . . . , x_{N}_{_{D}} of the at least one design concept in the engineering process including optimizing the representative design data samples x₁, . . . , x_{N}_{_{D}} with respect to at least one design target using the at least on representative design data sample x₁, . . . , x_{N}_{_{D}} as a starting point for the optimization process.

In an embodiment of the computer-implemented method, determining relevant description spaces includes at least the description spaces design specification subspace and design performance subspace. Processing the most representative design data samples x₁, . . . , x_{N}_{_{D}} of the at least one design concept in the engineering process includes varying design parameters in the design specification subspace of design specification parameters for the at least one representative design for developing design variants of the at least one design concept.

In the computer-implemented method according to an embodiment, processing the representative design data samples of the at least one design concept in the engineering process may include storing the representative design data samples x₁, . . . , x_{N}_{_{D}} of the at least one design concept as a reduced data set of the design concept.

According to an embodiment of the computer-implemented method, the determined at least one design concept includes the plurality of design data samples fulfilling constraints of
each design data sample x₁, . . . , x_{N}_{_{D}} is included in at maximum one design concept, and
all design features f₁, . . . , f_{N}_{_{F}} of all design data samples x₁, . . . , x_{N}_{_{D}} of the at least one design concept are similar, and
all design data samples x₁, . . . , x_{N}_{_{D}} assigned to the at least one design concept in a joint description space including all description spaces are assigned to the same at least one design concept in each of the description space of the plurality of description spaces.

Similar design features f₁, . . . , f_{N}_{_{F}} may mean that the design features f₁, . . . , f_{N}_{_{F}} have corresponding feature values that differ only by an amount, which is below a predetermined threshold.

The computer-implemented method according to an embodiment further includes:
determining at least one design concept including a plurality of design data samples x₁, . . . , x_{N}_{_{D}} from the acquired a dataset D includes:
determining plural concept candidates from the obtained dataset D based on at least a similarity of feature values of the design features f₁, . . . , f_{N}_{_{F}}, each concept candidate including a group of design data samples, for generating plural concept candidate configurations;
calculating a metric Q for the concept candidate configurations, the calculated metric Q defining a quality of the generated concept candidate configurations, the metric Q evaluating the design features f₁, . . . , f_{N}_{_{F}} of different description spaces of the plurality of description spaces; and
evaluating the plural concept candidate configurations based on the calculated metric Q to generate the at least one design concept.

In the computer-implemented method according to according to an embodiment, the similarity of feature values of the design features f₁, . . . , f_{N}_{_{F}} includes at least a similarity in a first description space, in a second description space and in a third description space.

Processing the representative design data samples x₁, . . . , x_{N}_{_{D}} of the at least one design concept in the engineering process in an embodiment may include optimizing a design of the physical object based on a fitness function, wherein the fitness function is based on at least one of the calculated metric Q and the selection criterion.

The computer-implemented method may have the dataset including design data samples x₁, . . . , x_{N}_{_{D}} of engineering design data, each data sample xᵢ representing a design of the physical object. Each of the plural description spaces is characterized by a single design feature fᵢ or a group of design features fᵢ, fⱼ, . . . , wherein the group of design features fᵢ, fⱼ, . . . includes one of a set of design data parameters of the physical object, a set of geometrical features of the physical object, a set of performance values of the physical object for defined conditions, and a latent representation of a machine learning approach, in particular of an auto-encoder or of a principal/independent component analysis PCA/ICA.

The computer-implemented method for performing a design process by analyzing design data of a physical object according comprises steps of: obtaining a dataset including a plurality of design data samples of design data, each data sample representing a design variation of the physical object, each data sample comprising a plurality of design features, each design feature included in one of a plurality of description spaces; determining plural concept candidates from the obtained dataset based on at least a similarity of feature values of the design parameters, wherein each concept candidate includes a group of design data samples, in order to generate plural concept candidate configurations; calculating a metric for the concept candidate configurations, wherein the calculated metric defines a quality of the generated concept candidate configurations, the metric evaluating the design parameters of different description spaces of the plurality of description spaces; evaluating the plural concept candidate configurations based on the calculated metric to generate concepts; determining a representative data sample for each of the concepts based on at least one selection criterion; outputting the determined representative data sample for each of the concepts; and performing the design process for the physical object based on the output representative data sample for each of the concepts.

The method according to the first aspect provides a capability to identify design concepts in design datasets using a metric that balances three components against each other: the number of design data samples within each design concept, the intersection of different design concepts within each description space and an intersection of the design concepts with the predefined preferences or constraints on values of features in some description spaces.

Furthermore, the method enables to identify groups of similar solutions in plurality of relevant description spaces and provides an objective measure, which considers all descriptions spaces and the relations of identified design data samples simultaneously.

The method provides a process for defining design concepts and selecting representative design data samples (or: archetypes), which identifies design data samples, which show the best trade-off characteristics in the dataset for a given design problem.

Design concepts contain design data samples, which are similar with respect to their feature values in each respective description space. Each design concept consists of designs samples, which belong to the same group in each description space simultaneously. For example, a design concept may contain design data samples that are similar with respect to all their design parameters, their geometrical feature values, their performance values for different environmental conditions, and other feature values.

In previously known approaches, defining design concepts has been restricted to two description spaces only. Design concepts were limited in scope to only deal with design parameters and a single set of performance values. In engineering applications, these two description spaces are traditionally considered to be the most relevant spaces. However, not only provide design concepts valuable insight into the design problem, but they also enable the engineer to derive representative design data samples for the design concepts. Representatives may be selected such that they represent an archetypal configuration of the design concept, meaning that they share a substantial number of features with other design data samples of the design concept they originate from. These representative design data samples may be used as prototypes for further design stages, such as a refinement of the initial design or serving as starting points for subsequent optimization studies under changed environmental conditions or case-based reasoning approaches. Since prototypes from different design concepts represent different parts of the search space of the dataset, they generate improvement potential in multiple directions.

Concept identification represents a particular type of clustering problem, where corresponding clusters represent design concepts in case the clustering of the design data samples is preserved within all description spaces. Known clustering approaches cannot achieve this target, contrary to the method according to the aspect of the invention defined above.

The method is able to identify and objectively assess meaningful design concepts based on an arbitrary number of description spaces and previously defined characteristics and preferences. The core of the method is the metric determining a quality for the concept candidate configuration distribution. The metric balances three components against each other: the number of design data samples within each design concept, the intersection of different design concepts within each description space and the intersection of the design concepts with the predefined preferences or constraints on feature values in some or all description spaces. The method enables specifying such preferences as feature value intervals, directions in the descriptions space or a set of particular solutions of interest.

Further, the method enables generating new and optimized design data samples, for example finding new design data samples in an independent data generation process, which persecutes the target of optimizing specific features in specific description spaces, of exploring specific other features, or of avoiding specific other features in specific other description spaces. In these applications, the representative design data samples or archetypical design data samples selected for the design concepts are selected to ensure to initialize and guide the search in the aforementioned applications most efficiently.

The method also achieves optimizing the evolvability of design data samples by selecting the design concepts and the selected representative design data samples such that when new design data samples are generated by a random variation of the feature values in one specific descriptions space, a distribution of the feature values of the design data samples in the other descriptions spaces is advantageous or complies with some predetermined preferences.

A further advantage of the method is its capability to perform dataset compression, for example compressing the large dataset D including a large initial number of design data samples to a reduced number of few representative design data samples, which still represent the most interesting part of the data set D. The reduced number of design data samples, the representative design data samples of the design concepts, may be used to reduce the required storage size and processing requirements for further data processing and analysis of the dataset D substantially. Selecting the representative design data samples and determining the design concepts in a way to represent the compressed dataset D achieves this advantageous effect.

The method further supports a design variant development, in particular by selecting the representative design data samples of the design concepts as a manageable amount of design variants that represent different parts of the design space.

The method also supports predicting feature values of new design data samples in all description spaces in which the new design data samples originally only include feature values in some selected description spaces by using the defined design concepts and their representative design data samples.

The method according to an embodiment includes the metric configured to evaluate the design features of at least three different description spaces.

The metric according to an embodiment is configured to define the quality based on at least one of a performance parameter, a distance to a Pareto front, an inclusion of predefined design data samples in the concept candidate configurations for each of the plurality of description spaces.

Before evaluating the concept candidate configurations using the calculated metric, specific v may be selected as design data samples of interest. Then, the metric may be penalized in case less or more of these design data samples of interest than desired are included in the corresponding concept candidate configuration.

In an embodiment, the method includes determining a predetermined number of the concept candidates for the plural concept candidate configurations. Alternatively, the method may include defining different numbers of the concept candidates for the concept candidate configurations from the dataset D simultaneously and evaluating the plural concept candidate configurations based on the metric and the different number of concept candidates in order to determine an optimized number of concept candidates for the plural concept candidate configurations. Alternatively, the method may optimize, based on the metric included in a fitness function, the similarity of the parameter values of the design features of the concept candidates in the step of determining the concept candidate configurations.

A fitness function is a particular type of objective function that is used to summarize, by a single or multiple numerals, how close a given design solution comes to achieving preset targets. Fitness functions are used in evolutionary and genetic algorithms and generally in numerical optimization to guide simulation and optimization processes towards optimal design solutions.

The at least one selection criterion comprises at least one of a predefined preference criterion, in particular a high performance, or low maintenance cost, or low weight, or any other criterion relevant to performance. The at least one selection criterion may comprise at least one of a determination criterion calculated based on a composition of the design concept, in particular based on a distance to a mean computed based on feature values of the design parameters of the design data samples of the design concept, and a suitability as a starting point for performing the optimization process for the physical object, in particular preferring low variations of feature values in all description spaces for a small variation of the feature values of the representative data sample.

The metric may output increased numerical values for an increased quality of the concept candidate configuration.

The quality of a particular concept candidate configuration depends on a number of design data samples of the dataset D being included in all of the plural concept candidates of the particular concept candidate configuration, in particular the quality of the particular concept candidate configuration decreases for an increasing number of design data samples of the dataset D not included in any of the concept candidates of the concept candidate configuration.

Additionally or alternatively, the quality of the particular concept candidate configuration is high in case every data sample of the dataset D is associated with one concept candidate of the concept candidate configuration.

Additionally or alternatively, the quality of the particular concept candidate configuration is high in case the number of design data samples of each concept candidate is neither below a first threshold nor above a second threshold.

Additionally or alternatively, the quality of the particular concept candidate configuration is high in case the design data samples of all concept candidates of the particular concept candidate configuration include all the design data samples of a predetermined portion of the design data samples in the dataset D.

Additionally or alternatively, the quality of the particular concept candidate configuration is high in case each concept candidate approximates predetermined target characteristics in each description space, wherein, in particular, the target characteristics base at least on value ranges for particular feature values in particular description spaces, on a distance of the particular feature values of the particular description spaces to predetermined feature values.

In an embodiment, the method includes evaluating the metric for the concept candidate configurations comprising maximizing the metric using a numerical optimization algorithm, in particular a gradient based algorithm or an evolutionary or a swarm-based optimization algorithm, by changing the number of concept candidates of the concept candidate configuration and an association of each design data sample x₁, . . . , x_{N}_{_{D}} of the design data in each description space with none, one or more concept candidates.

The step of evaluating the metric for the concept candidate configurations comprises using binary variables describing an association of each design data sample in each description space to each concept candidate directly as optimization parameters for maximizing the metric.

Alternatively, the step of evaluating the metric for the concept candidate configurations comprises defining geometrical regions in each description space, which define an affiliation of the design data samples x₁, . . . , x_{N}_{_{D}} to the concept candidates, and using geometric variables characterizing the geometric regions.

The step of calculating the metric for the concept candidate configurations according to an embodiment comprises counting a number |C_{αl}| of the design data samples x₁, . . . , x_{N}_{_{D}} for each concept candidate in each description space, wherein C_{αl} is the set of design data samples x₁, . . . , x_{N}_{_{D}} associated with concept candidate α∈1, . . . , N_{C} in a description space l∈1, . . . , N_{D}, counting numbers of design data samples associated with multiple concept candidates in one description space, counting numbers of design data samples not associated with any concept candidate, determining a size of the concept candidates in each description space. The embodiment of the method proceeds by calculating a concept quality measure Q_{α} of one concept candidate α according to

$${Q}_{α} = {\prod }_{k , l \neq k}^{{N}_{DS}} \sqrt[{N}_{DS}]{\frac{\vert \{ x ∈ {C}_{α k} ⋂ {C}_{α l} \vert x ∉ {⋃}_{β = 1 , β \neq α}^{{N}_{c}} {C}_{β k} \} \vert}{\vert {C}_{α k} \vert}} {F}_{S} ( \frac{\vert {C}_{α k} \vert}{{N}_{D}} ) \qquad ( 2 )$$

wherein N_{DS} denotes a number of the description spaces, the descriptions spaces are enumerated by Roman letters l, k, N_{C} denotes the number of concept candidates, the design concepts are enumerated by Greek letters α, β, C_{αk} represents the set of design data samples which are associated to design concept α in descriptions space k, and a factor

$${F}_{S} ( c ) = \{ \begin{matrix}\sqrt{1 - {( \frac{c - s}{s} )}^{2}} , & if c < s \\ 1 , & if s < c < 1 - s \\ \sqrt{1 - {( \frac{c - 1 + s}{s} )}^{2}} , & if c > 1 - s\end{matrix} \qquad ( 3 )$$

with

$$c = \frac{\vert {C}_{α k} \vert}{{N}_{D}}$$

and a freely selectable number 0≤s≤1, which favors the sizes of each concept to be between sN_{D} and (1−s)N_{D}, where N_{D} is the total number of design data samples in the dataset D. The embodiment proceeds by calculating the metric Q by aggregating the individual concept quality measures Q_{α} by computing a sum, Q=Σ_{α}^{N}^{_{C}}Q_{α}, or a product Q=Π_{α}^{N}^{_{C}}Q_{α} or by using another monotonic aggregation function of the individual concept quality measures Q_{α} for quantifying the quality of a concept candidate configuration.

The method according to an embodiment, further includes calculating the metric Q for the concept candidate configurations by regarding additionally preferred feature values of the design features represented in concept candidates by reducing the concept quality measure Q_{α} of one concept candidate if the preferred feature values are not included in a concept candidate according to

$${Q}_{a P} = {Q}_{a} \cdot {F}_{P} ( {a}_{α} ) \qquad ( 4 )$$

$$wherein$$

$${F}_{P} ( {a}_{α} ) = \{ \begin{matrix}\sqrt{1 - {( \frac{{a}_{α} - p}{p} )}^{2}} , & if {a}_{α} < p \\ 1 , & if p < {a}_{α} < 1 - p \\ \sqrt{1 - {( \frac{{a}_{α} - 1 + p}{p} )}^{2}} , & if {a}_{α} > 1 - p\end{matrix} \qquad ( 5 )$$

with a freely selectable parameter 0≤p≤1 and

$${a}_{α} = \frac{{\sum }_{i = 1}^{{N}_{DS}} \vert {C}_{α i} ⋂ {P}_{i} \vert}{{\sum }_{i = 1}^{{N}_{DS}} \vert {P}_{i} \vert} . \qquad ( 6 )$$

Pᵢ with i=1, . . . , N_{DS} denotes the set of design data samples with the preferred feature values in a description space i. A function F_{P}(a_{α}) measures a fulfilment of a requirement on the preferred feature values in the description spaces, and the requirement is formulated by defining a set of design data samples of interest which should be included into each concept candidate. The method proceeds by calculating the metric Q by aggregating the individual concept quality measures Q_{α} by computing the sum Q=Σ_{α}^{N}^{_{C}}Q_{αP}, or the product Q=Π_{α}^{N}^{_{C}}Q_{αP}, or by using another monotonic aggregation function of the concept quality measure Q_{α} for quantifying the quality of a concept candidate configuration.

Calculating the metric Q for the concept candidate configurations according to an embodiment of the method comprises utilizing mutual information for quantifying how much information is gained about an association of the design data samples with one specific concept candidate in one description space by acquiring knowledge about the association of the design data samples with the one specific design concept in another description space, and utilizing additionally information gained by knowing an association of design data samples with a union of two concept candidates provides on the association of design data samples with the intersection of the two concept candidates in one description space. The method of this embodiment then proceeds by summing over the gained combinatorial information according to

Q=Σ_{α,β≠α,j,k≠j}I(C_{αj},C_{αk})[1−I({C_{αj}∪C_{βj}},{C_{αj}∩C_{βj}})]Fₛ(|C_{αj}|/N_{D}) (7)

wherein I(X, Y) is the mutual information of the sets of variables X and Y, for calculating the metric (Q) based on applying information theory.

According to an embodiment of the method, performing the design process may comprise obtaining at least one new data sample, wherein for the at least one new data sample for at least one of the description spaces the feature values for the plurality of design features are unavailable. The step of performing the design process proceeds by associating the at least one new data sample to a specific design concept of the design concepts based on the available feature values for the plurality of design features. The method then predicts feature values for the plurality of design features of the new data sample for which the feature values for the plurality of design features are unavailable based on the associated specific design concept.

In the following description of an embodiment, an airfoil is used as a particular example for a physical object. Nevertheless, the physical object may be any other physically existing technical object, which results from performing an engineering design process, for example a vehicle, or a vehicle part such as a vehicle chassis, a sea, air or space vehicle or part thereof, a part of a machine, such as a turbine blade, for example.

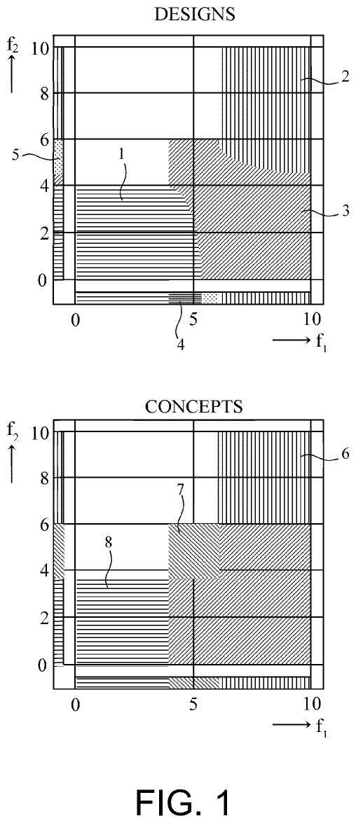

FIG. 1 illustrates an example of a two-dimensional description space of a plurality of design data samples x₁, . . . , x_{N}_{_{D}} and a plurality of design concepts identified in the description space.

FIG. 1 shows to illustrations of the two-dimensional description space with feature f₁ in the horizontal direction (abscissa) and feature f₂ in the vertical direction (ordinate). The areas 1, 2, and 3 in the upper chart of FIG. 1 each illustrate parts of the description space, in which design data samples of a design dataset D may be located. Feature f₁ includes a range 4 of feature values around the feature value of 5, where the areas 1 and 3 are ambiguous with respect to feature f₁. Feature f₂ includes a range 5 of feature values between feature values of 4 and 6, where the areas 2 and 3 are ambiguous with respect to feature f₂.

The lower chart of FIG. 1 shows an example of design concepts in the same two-dimensional description space with feature f₁ in the horizontal direction and feature f₂ in the vertical direction as the upper chart. Three design concepts 6, 7, 8 are identified and illustrated in the lower chart of FIG. 1. Each of the concepts 6, 7, 8 includes a respective unambiguous range of features values of the features f₁ and f₂. Identified design concepts 6, 7, 8 do not overlap in the two-dimensional description space. The respective ranges of the features f₁ and f₂ of each design concept 6, 7, 8 do also not overlap neither in the direction of feature f₁ nor in direction of feature f₂. An assignment of design data samples to design concepts 6, 7, 8 (cluster assignment) persists between all considered description spaces: the joint space of all features f₁, f₂ of a plurality of features f₁, f₂, and all relevant description spaces (subspaces) of at least one of the plurality of features f₁, f₂. In consequence, design data samples, which are assigned to a same design concept 6, 7, 8 in the joint space, are also assigned to the same design concept 6, 7, 8 in all description spaces (subspaces).

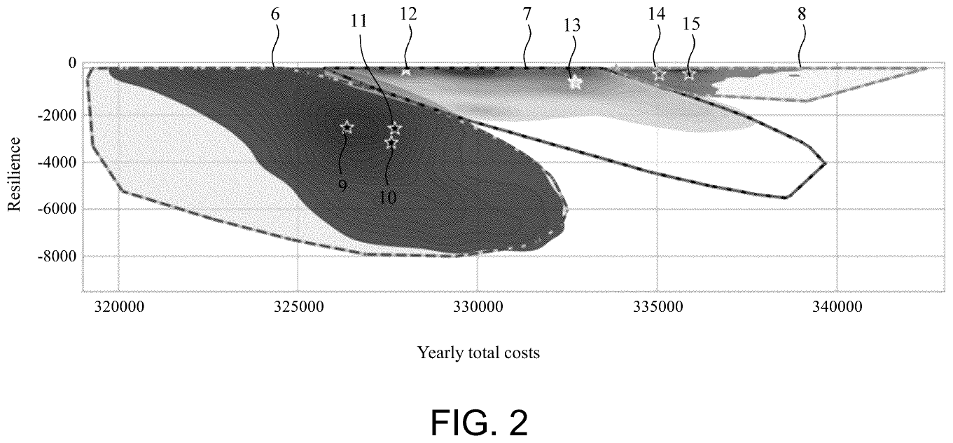

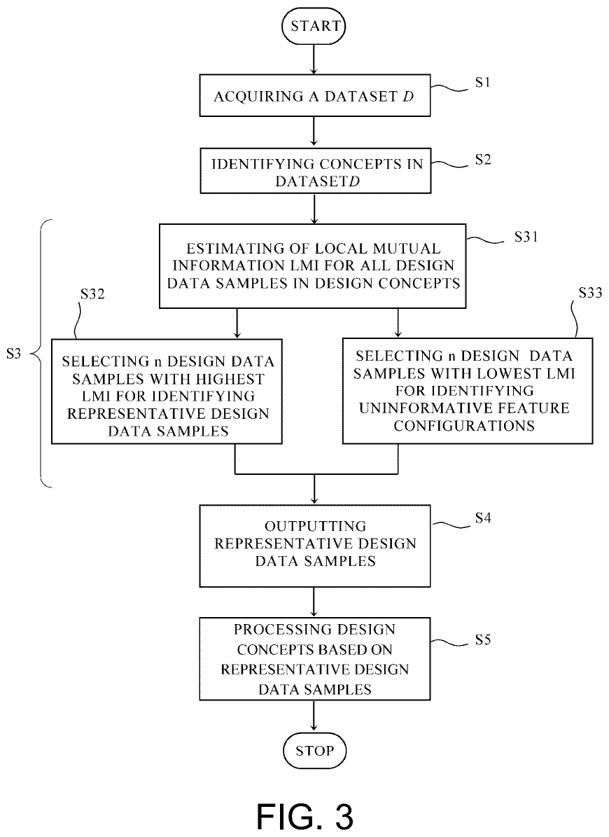

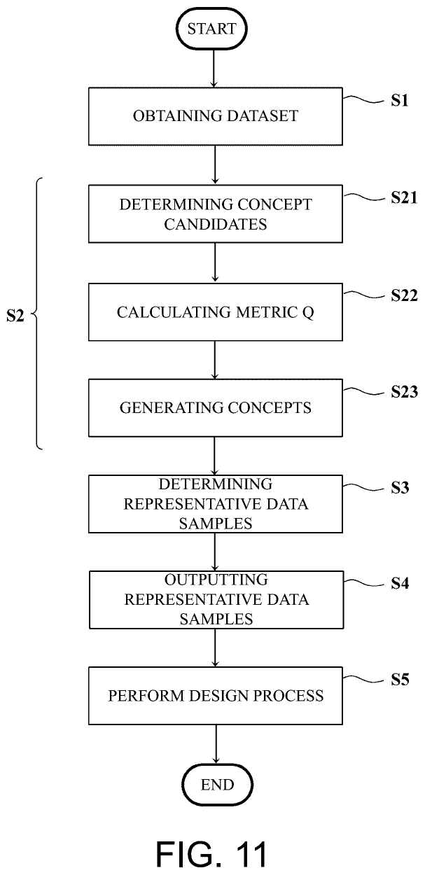

FIG. 2 illustrates an example of a two-dimensional description space with three design concepts 6, 7, 8 identified in the description space and representative designs for each design concept 6, 7, 8. For the design concept 6, three representative designs 9, 10, 11 are shown. For the design concept 7, two representative designs 12, 13 are shown in FIG. 2. Two further representative designs 14, 15 are shown in FIG. 2 for the design concept 8. The identified representative designs 9, 10, 11, 12, 13, 14, 15 of FIG. 2 each are selected in order to represent the respective design concept 6, 7, 8 by being selected from regions of a high density of design data samples on the one hand. On the other hand, identified representative designs 9, 10, 11, 12, 13, 14, 15 of FIG. 2 each are selected in order to differentiate the respective design concept 6, 7, 8 from the other design concepts with respect to the features of the design space arranged in direction of the abscissa and the ordinate axis respectively. The number of the representative designs 9, 10, 11, 12, 13, 14, 15 and their respective spatial arrangement in the design space provide a meaningful representation of the dataset D of design data samples. The method according to the embodiment provides an advantageous process for identifying design concepts 6, 7, 8 and respective representative designs 9, 10, 11, 12, 13, 14, 15 for the identified design concepts 6, 7, 8. The method will be discussed in more detail with reference to the flowcharts of FIG. 3 with emphasis on determining representative designs 9, 10, 11, 12, 13, 14, 15 and FIG. 11 for identifying design concepts 6, 7, 8 in the dataset D including a plurality of design data samples. Taking into account the specific constraints on concept identification, and, in particular, further considering the similarity or correlation between different description spaces achieves such advantageous distribution of identified design concepts 6, 7, 8 and the determined representative designs 9, 10, 11, 12, 13, 14, 15 contrary to the known approaches starting from the complex design dataset D. This provides further advantages in the subsequent processing steps in terms of required computational power for optimization processes due to providing suitable starting points in terms of the representative designs or in terms of required memory space for storing data samples by deleting the least representative design data samples.

FIG. 3 depicts a simplified flowchart, which depicts method steps of an embodiment of the computer-implemented method for performing a design process by processing design data of a physical object.

In a first step S1, the method acquires a dataset D including a plurality of design data samples x₁, . . . , x_{N}_{_{D}} of design data, each design data sample xᵢ representing one design variation of the physical object and comprising a plurality of design features f₁, . . . , f_{N}_{_{F}}, each design feature fᵢ included in at least one of a plurality of description spaces.

In a subsequent step S2, the method proceeds with determining at least one design concept including a plurality of design data samples x₁, . . . , x_{N}_{_{D}} from the acquired dataset D based on at least a similarity of feature values of the design features f₁, . . . , f_{N}_{_{F}}, wherein each design data sample x₁, . . . , x_{N}_{_{D}} comprises design features in at least two of the description spaces. FIG. 11 and the corresponding section of the discussion of embodiments provide further detail on step S2.

In subsequent steps S31, S32, and S33 the method proceeds with determining a representative data sample for each of the concepts based on at least one selection criterion.

In step S31, the method calculates a local similarity measure between the at least two description spaces for each design data sample x₁, . . . , x_{N}_{_{D}} included in the determined at least one design concept.

In particular, local similarity describes how informative a value of a design data sample in one description space is with respect to a value of the same design sample in another description space. It describes how predictable the value in one description space is from the value in another description space. An implementation of a local similarity measure is the mutual information MI. In particular, a local mutual information may be used to implement the local similarity measure, e.g., a sample-wise computed local mutual information (LMI).

Generally, mutual information I(X; Y) is defined as

$$I ( X ; Y ) = {\sum }_{x , y} p ( x , y ) log \frac{p ( x \vert y )}{p ( x )} . \qquad ( 8 )$$

Generally, mutual information I(X; Y) quantifies a dependency between two variables X and Y as their deviation from a statistical independence. The mutual information I(X; Y) may be interpreted for individual realizations of random variables X and Y such that one obtains a local interpretation of the mutual information as local mutual information (LMI) i(x; y),

$$i ( x ; y ) = log \frac{p ( x \vert y )}{p ( x )} . \qquad ( 9 )$$

Thus, the LMI i(x; y) quantifies how the probability of observing outcome x changes when observing outcome y, compared to the prior probability of observing outcome x.

The LMI quantifies the information shared between individual realizations of X and Y. It relates to the mutual information by the average over all possible realizations x, y, such that the mutual information is the average of the individual deviations from independence, weighted by their joint probability, and measured on a logarithmic scale.

In steps S32 and S33, a number of design data samples x₁, . . . , x_{N}_{_{D}} based on the calculated local similarity measure from the plurality of design data samples x₁, . . . , x_{N}_{_{D}} included in the determined at least one design concept are selected as at least one of most representative designs and least representative designs.

In particular, the designs with a highest LMI within a design concept are identified as representative design data samples for the respective design concept. For these representative designs, when varying the specification of the archetype designs, a probability of finding designs samples with a similar performance is highest amongst all design data samples of the plurality of designs samples of the design concept. This characteristic is advantageous when developing variants of a design, while simultaneously preserving desired performance values.

In step S32, a number of design data samples x₁, . . . , x_{N}_{_{D}} based on the calculated local similarity measure from the plurality of design data samples x₁, . . . , x_{N}_{_{D}} included in the determined at least one design concept are selected as most representative designs and least representative designs.

In step S33, a number of design data samples x₁, . . . , x_{N}_{_{D}} based on the calculated local similarity measure from the plurality of design data samples x₁, . . . , x_{N}_{_{D}} included in the determined at least one design concept are selected as at least one least representative design.

The steps S32 and S33 may be performed alternatively or both. The steps S32 and S33 may be performed sequentially or at least partially in parallel.

In step S4, the method proceeds by outputting the selected most representative design(s) to an engineering process for further processing.

Additionally or alternatively, in step S4, the method may delete the least representative design(s) from the design data samples x₁, . . . , x_{N}_{_{D}} of the respective design concept.

The method proceeds with processing at least one of the most representative design data samples of the at least one design concept in the engineering process in step S5.

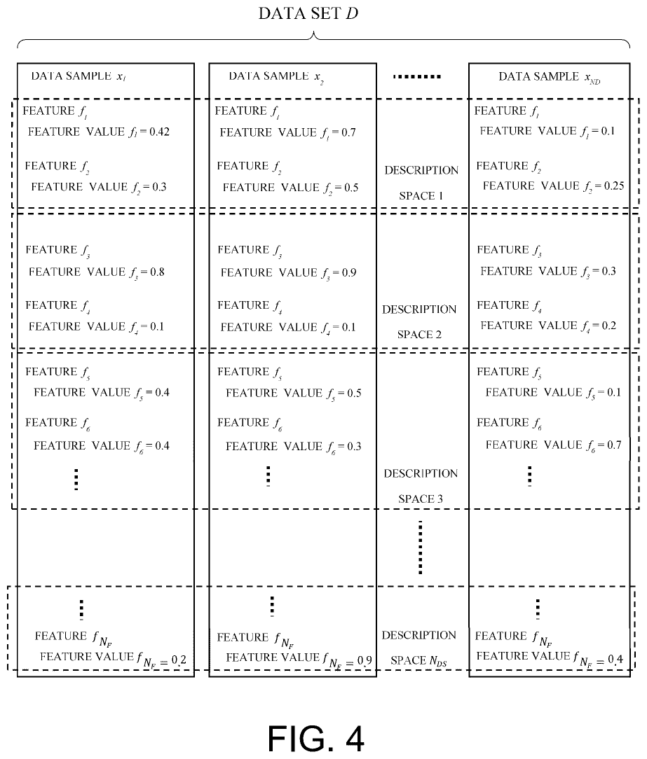

FIG. 4 illustrates a dataset D including multiple design data samples x₁, . . . , x_{N}_{_{D}}, the design data samples including features f₁, . . . , f_{N}_{_{F}} in description space 1, description space 2, . . . , up to description space N_{DS}.

The term design data samples (or: data sample) refers to an element of the dataset D denoted by xᵢ. The data sample xᵢ represents a collection of all features f_{α} attributed with a data sample in expression (3)

xᵢ=(f₁,f₂, . . . ,f_{N}_{_{F}}), (10)

In expression (3), N_{F} is a total number of features f_{α}. Therefore, a dimensionality of the data sample xᵢ, is N_{F}:

xᵢ∈ [symbol] ^{N}^{_{F}} (11)

The term feature (also: parameter) denotes the elements of each data sample xᵢ. Each data sample xᵢ is characterized by multiple features denoted by f_{σ}, with σ=1, . . . , N_{F}. For example, in case of an airfoil design problem, an airfoil corresponding to a data sample xᵢ can be characterized by design parameters of a constructive representation, by geometrical features, and by performance criteria, in order to provide a non-exhaustive list of three groups of parameters f_{σ}.

The features f_{σ} of the constructive representation (design parameters) may include control points of a spline representation, for example.

The features f_{σ} of the geometrical representation (geometrical parameters) may include a maximal airfoil thickness, an airfoil thickness at predefined fixed chord length positions, leading- and trailing-edge radii, for example.

The parameters f_{σ} of the performance criteria (performance features, performance values) may include values for lift coefficients and values for drag coefficients for predetermined air velocities and angles of attack, a value for weight, for example.

The term feature value (parameter value) denotes a value of a specific feature f_{σ} for a specific data sample xᵢ. For example, for the feature “maximal airfoil thickness”, the feature value might be “0.42”.

The term design parameters refers to a set of constructive design parameters pₘ, in case the dataset D is the result of a design process, in which each resulting data sample xᵢ is a potential solution to a specific problem. The design is typically defined by a set of constructive design parameters pₘ. The design parameters pₘ, enable to construct the actual design therefrom. For example, in the specific case of an airfoil design, the design parameters pₘ may be the control points of the NURBS representation of the airfoil design.

Alternatively, displacement variables for a set of deformation control points which specify the FFD deformation of a given baseline airfoil design may form the design parameters pₘ.

In the general context, design parameters pₘ are one type of parameters in the sense of features f_{σ} of a data sample xᵢ.

The term evolvability describes a specific capability of a data sample xᵢ, meaning its characteristic to be easily adjustable to changing environmental conditions and the corresponding changes in the evaluation criteria. For the dataset D being the result of a design process, the characteristic of evolvability amounts to the capability of design solutions to be easily adapted to changing environmental conditions or to changed design targets.

The term archetype refers to a data sample xᵢ, which is representative of a whole set of design data samples xᵢ.

The term design is also used to denote the engineering discipline of design. Specific examples include, but are not limited to, aerodynamic performance evaluation, structural mechanics performance evaluation, crashworthiness assessment, and noise, vibration and harshness (NVH) evaluations.

The term description space corresponds to a type of features, sometimes also called feature category. Features can be categorized into different types of features, wherein each type is associated with a specific semantic meaning and called a description space, denoted by [symbol] ⱼ with j=1, . . . , N_{DS}. The parameter N_{DS} denotes the total number of description spaces [symbol] ⱼ. Each group of features of one type is referred to as description space:

[symbol]

ⱼ={f_{σ}:σ=σ_{j,min}, . . . ,σ_{j,max}}, (12)

wherein the index σ enumerates the subset of features of the data sample xᵢ which defines the descriptions space j. For the specific example of the airfoil design, possible description spaces include at least the spaces spanned by
(1) all design parameters (description space [symbol] ₁);
(2) all geometrical features of the airfoil design, e.g., maximal airfoil thickness, airfoil thickness at predefined fixed chord length positions, leading- and trailing-edge radii, . . . (description space [symbol] ₂);
(3) all performance values (criteria) of one discipline (lift, drag, torque, . . . ) at airspeed U₁ and angle of attack α₁ (description space [symbol] ₃);
(4) all performance criteria of one discipline (lift, drag, torque, . . . ) at airspeed U₂ and angle of attack α₁ (description space [symbol] ₄);
(5) all performance criteria of one discipline (lift, drag, torque, . . . ) at airspeed U₁ and angle of attack α₂ (description space [symbol] ₅);
(6) all performance criteria of another discipline (stiffness, weight, vibrational eigenfrequencies, . . . ) at airspeed U₁ and angle of attack α₂ (description space [symbol] ₆).

It is evident that the dataset D of the particular example of airfoil design may include a plurality of further possible specific description spaces.

In a predetermined engineering design data set, the designs are characterized in multiple description spaces. A common description space is the space of design parameters, which are used to create the design, e.g., parameters of the parametric CAD representation. A further common description space is the objective space, which comprises all considered performance values. Depending on the actual design problem, additional description spaces might be useful, such as statistical or geometrical features derived from the design, or flow field properties of a given design in case of fluid dynamic assessment. Identifying design concepts amounts to finding different groups of designs, which share similar properties in all description spaces simultaneously.

The term design concept (short: concept) denotes a set of design data samples s xᵢ that are similar in all description spaces l. Each design concept defines a set of design data samples xᵢ, in each description space l and all design data samples xᵢ belong to the same group in each description space l simultaneously. A design concept constitutes an abstract representation of a set of designs sharing similar properties in terms of their design parameters along with comparable performance measures and a comparable behavior.

Advantages of the method according to a particular embodiment are illustrated by discussing a particular example of airfoil design.

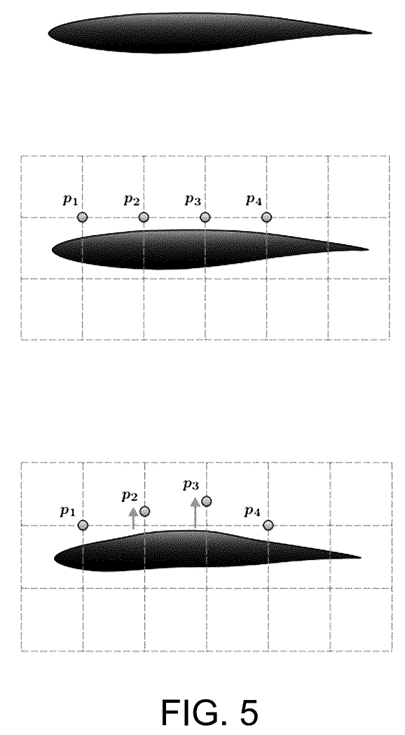

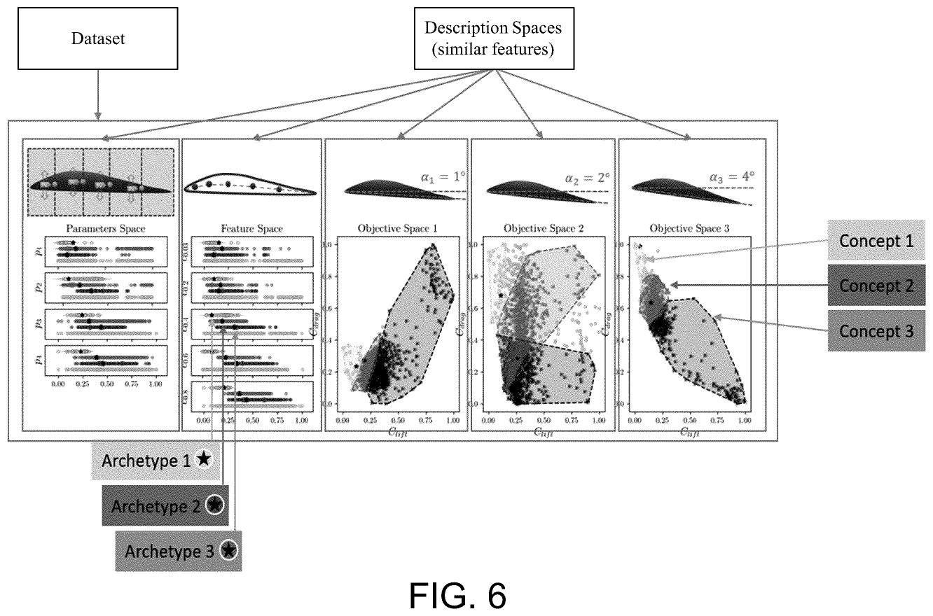

The two-dimensional airfoil profiles depicted in FIG. 5 are generated using a free-form deformation. The RAE2822 base profile in the upper portion of FIG. 5 is embedded in a lattice in the center portion of FIG. 2. Four of the lattice control points P₁, P₂, P₃, and P₄ are defined as free parameters. In order to generate the airfoil profile shown in the lower part of FIG. 5, the lattice control points P₁, P₂, P₃, and P₄ are varied. The entire dataset D underlying FIG. 2 contains around 2500 design data samples that are created using several evolutionary optimization runs. The particular example of airfoil design uses a dataset D comprising several two-dimensional airfoil profiles. The airfoil profiles are constructed by deforming an RAE2822 base airfoil profile in a free-form-deformation setup, as illustrated in FIG. 6. For each airfoil profile constructed from the base airfoil profile, the method records in total, fifteen parameter values.

Four design parameters in the first description space describe a deformation of the profile and hence define the airfoil profile.

Additionally, the position of an airfoil camber line is calculated for five different positions, forming five features for each airfoil profile in the second description space.

In the particular example of airfoil design, an aerodynamic behavior of all airfoil profiles is evaluated at three different angles of attack, in the third, fourth and fifth description spaces, respectively.

This may be performed using any of known examples of a customized numerical simulation software for a solution of continuum mechanics problem, including computational fluid dynamics. A specific, nevertheless non-limiting example for this is the OpenFoam® software (OpenFoam® for Open Source Field Operation and Manipulation).

For each profile and angle of attack, the drag and lift coefficients are derived as performance indicators. Three different angles of attack are taken into consideration because airfoils typically operate under different conditions and a high performance under one angle of attack may not guarantee a high performance under different angles of attack.

As shown in FIG. 6, the parameters are split into five description spaces: the first description space is the design parameter space, the second description space is the geometric feature space, and the third, fourth and fifth description space are the objective space 1, objective space 2, and objective space 3, respectively. The target of the concept identification process is to identify reasonable design concept s for these five description spaces. Identifying such design concept s for the five description spaces requires determining groups of design concepts that share similarities with respect to all of the above-mentioned properties.

In order to incorporate the preference, which is to include the best trade-off solutions of the design concept s during the concept identification process, a range of high performing trade-off samples is selected as sample designs of particular interest.

In the particular example of airfoil design, all non-dominated solutions of each of the three performance description spaces and additionally some sample designs that are nearby are selected.

For example, all design data samples with a maximum distance in terms of lift and drag coefficient of less or equal than 0.05 to an existing solution may be considered to be nearby.

In the particular example of airfoil design, the method may target to define meaningful design concepts for such dataset D, for example, the groups of airfoil designs, which fulfill the following requirements:

(1) A group of airfoil designs should have similar feature values in all description spaces.

The requirement (1) provides the effect that a design concept containing airfoil designs with high lift values at large angles of attack, should also contain airfoils designs, which have similar lift and drag values at all other angles of attack, as well as similar design parameters and geometrical features, for example. Therefore, if the design target is a high lift airfoil, the identified design concept s provide insights on the other performance criteria at other angles of attack as well as the knowledge on trade-off relations of similar data samples with similar geometrical features.

(2) Each data sample, which is identified to belong to one design concept in one description space needs to belong to the same design concept in all other description spaces as well.

Requirement (2) reflects the necessary conditions that the definition of a design concept is actually valid over all description spaces.

(3) The design concepts must not have a considerable overlap.

Requirement (3) means, that the number of d data samples belonging to more than one design concept should be limited.

(4) A design concept should contain a reasonable fraction of data samples.

A design concept may neither contain only a single data sample, and a design concept may not consist of the entire dataset D. The specific meaning what the term “reasonable” in requirement (4) may refer to, for example, a minimal size and a maximal size of the design concepts, may be specifiable by a user.

(5) Constraints or preferences of the user need to be included. For example, the user wants the design concepts to include best trade-off solutions in at least one description space or up to all performance description spaces.

(6) A small set of representative data samples (archetypes) from every design concept should be provided, which reflect some predetermined criteria (general criteria). Alternatively or additionally, the user may provide criteria (user-provided criteria).

For example, the representative data samples cover and represent a Pareto front of the complete objective space. Alternatively, the representative data samples may represent the complete dataset D as best as possible.

### Mathematical Description:

In order to assess the quality of a given definition of a set of design concepts, the method evaluates the objective numerical measure Q (metric) for a given definition of design concepts, which corresponds to a configuration of concept candidates:

Q=Π_{α}^{N}^{_{C}}Q_{αP} (13)

In expressions (13) and (14), the metric Q is a numerical measure for a given definition of design concepts, N_{C} is the number of design concepts, and the Greek indices α, β refer to the individual design concept. The metric Q comprises the product of a metric Q_{αp} for each design concept α of (5):

$${Q}_{α P} = {\prod }_{k , l \neq k}^{{N}_{DS}} \sqrt[{N}_{DS}]{\frac{\vert \{ x ∈ {C}_{α k} ⋂ {C}_{α l} \vert x ∉ {⋃}_{β = 1 , β \neq α}^{{N}_{c}} {C}_{β k} \} \vert}{\vert {C}_{α k} \vert}} {F}_{S} ( \frac{\vert {C}_{α k} \vert}{{N}_{D}} ) {F}_{P} ( \frac{{\sum }_{i = 1}^{{N}_{DS}} \vert {C}_{α i} ⋂ {P}_{i} \vert}{{\sum }_{i = 1}^{{N}_{DS}} \vert {P}_{i} \vert} ) \qquad ( 14 )$$

For each description space, indexed by Roman letters k, l, the fractional term below the root evaluates the number of samples that belong to only one design concept divided by the total number of samples |C_{αk}| associated with that design concept in description space k. A high overlap between the individual design concepts leads to low values for the fractional term and vice versa. In (7), the parameter N_{DS} denotes the number of description spaces and N_{C} the number of design concepts. Cₐₖ is the set of samples associated with design concept α in description space k. The product of the roots for all non-identical description space combinations is multiplied by the factor F_{S} in (14), which is defined by expression (15):

$${F}_{S} ( \frac{\vert {C}_{α k} \vert}{{N}_{D}} ) \qquad ( 15 )$$

with the parameter S according to (16

0≤S≤1, (16)

and with N_{D} representing a total number of samples in the dataset D. The size of each design concept is therefore favored to be between

SN_{D} (17)

and

(1−S)N_{D} (18)

The factor F_{P} in expression (14) is given by expression (19):

$${F}_{P} ( \frac{{\sum }_{i = 1}^{{N}_{DS}} \vert {C}_{α i} ⋂ {P}_{i} \vert}{{\sum }_{i = 1}^{{N}_{DS}} \vert {P}_{i} \vert} ) \qquad ( 19 )$$

Pᵢ with i=1, . . . , N_{DS} denotes the preferred parameter values in a description space i.

Pᵢ favors design concepts that contain a specific proportional range of preference samples or constraints. The functions F_{S}(c) and F_{P}(a_{α}) are defined by:

$${F}_{S} ( c ) = \{ \begin{matrix}\sqrt{1 - {( \frac{c - s}{s} )}^{2}} , & if c < s \\ 1 , & if s < c < 1 - s \\ \sqrt{1 - {( \frac{c - 1 + s}{s} )}^{2}} , & if c > 1 - s\end{matrix} \qquad ( 20 )$$

$${F}_{P} ( {a}_{α} ) = \{ \begin{matrix}\sqrt{1 - {( \frac{{a}_{α} - p}{p} )}^{2}} , & if {a}_{α} < p \\ 1 , & if p < {a}_{α} < 1 - p \\ \sqrt{1 - {( \frac{{a}_{α} - 1 + p}{p} )}^{2}} , & if {a}_{α} > 1 - p\end{matrix} \qquad ( 21 )$$

The parameters s, p∈[0, 1] in expressions (20), (21) can be set to favor a desired concept size and the proportion of preferred data samples a design concept contains, respectively.

The identification of reasonable design concepts is performed in an optimization process. Each design concept α is parametrized by an ellipsoid in each description space l, where each of the data samples inside the ellipsoid in that description space l is considered to belong to that design concept α. For an n-dimensional description space l, an ellipsoid needs to be defined with a number of parameters

n(n+3)/2 (22)

with n denoting the number of dimensions of the description space in expression (22).

The discussed specific example of airfoil design pursues the target of identifying three airfoil design concepts. The description spaces have a dimension of four for a first description space of design parameters, a dimension of five for a second description space of geometric features, and a dimension of two for the third, fourth, and fifth description space of each objective description space. According to expression (22), a total number of parameters defining the design concepts is given by expression (23):

3·(14+20+5+5+5)=147 (23)

An evolutionary algorithm modifies these 147 parameters by maximizing the metric Q according to (6). The evolutionary algorithm may be an example of a particle-swarm optimization (PSO), a covariance matrix adaptation evolutionary strategy (CMA-ES) or any optimization algorithm. Performing the evolutionary algorithm enables to arrive at an optimal distribution of design concepts by maximizing the metric Q of expression (6).

In the particular example of airfoil design, the method identifies three design concepts, each design concept of the three design concepts covering parts of all three description spaces.

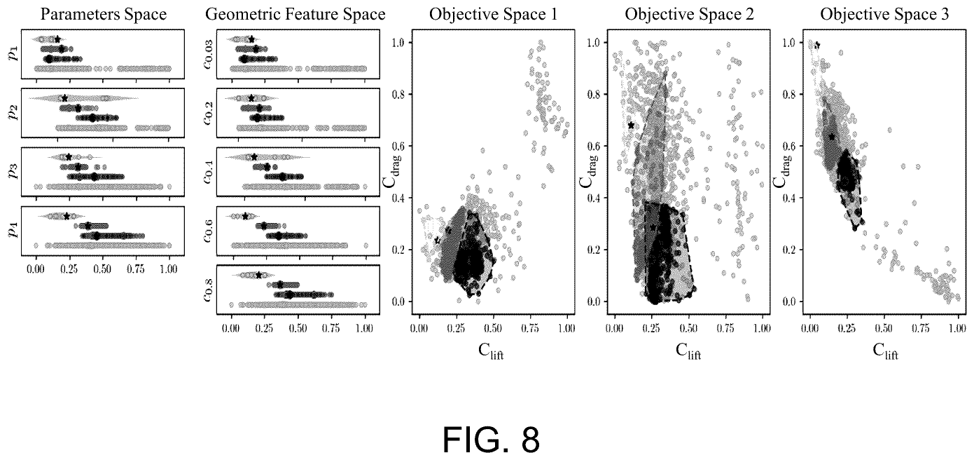

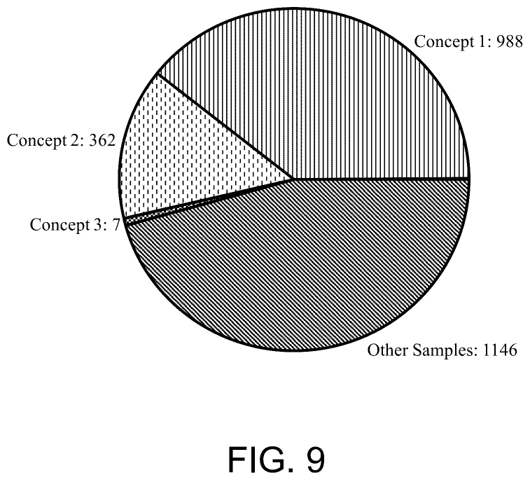

FIG. 8 shows a number of d data samples that are associated with each of the three identified design concepts and an overlap of the three design concepts in each description space. In FIG. 9, the method identifies three design concepts that vary highly in their extent.

In the particular example of airfoil design, for each of the three design concepts, the data sample that is closest to a geometric mean of its respective concept in the parameter space is selected as a representative data sample for the respective concept. Each representative data sample represents a design concept in each description space and can be used to further develop a manageable amount of design alternatives from the representative data sample.

The design concepts can further be used to predict features of additional data samples. For data samples that have not been generated in the original process, or for which not all feature values have been derived, only limited information might be available.

In the particular example of airfoil design, additional airfoil samples that were not generated in a free form deformation process might be added to the dataset D. The additional airfoil data samples cannot be described within the original parameter space, however, all feature values for each feature in the geometric feature space can be computed. Based on a proximity of the additional data samples to the originally discovered design concepts in the geometric feature space, their feature values can be predicted. Any additional data samples that lie within the extent of a design concept in one description space will likely belong to the design concept in the other description spaces.

In the particular example of airfoil design, the calculation of the aerodynamic values drag coefficient and lift coefficient requires most of the computation time. In order to predict these aerodynamic values for additional samples, the method uses the identified design concepts to predict these aerodynamic values for additional data samples thus creates a significant benefit, since the computation time will decrease significantly.

FIG. 6 shows a normalized dataset D in five description spaces in the airfoil design implementation of the method. FIG. 6 arranges the five description spaces from left to right, the (design) parameter space, the geometric feature space, a first objective space, a second objective space and a third objective space arranged.

In the parameter space and in the geometric feature space, for each feature included in the respective description space, a distribution of data samples is shown for each individual parameter.

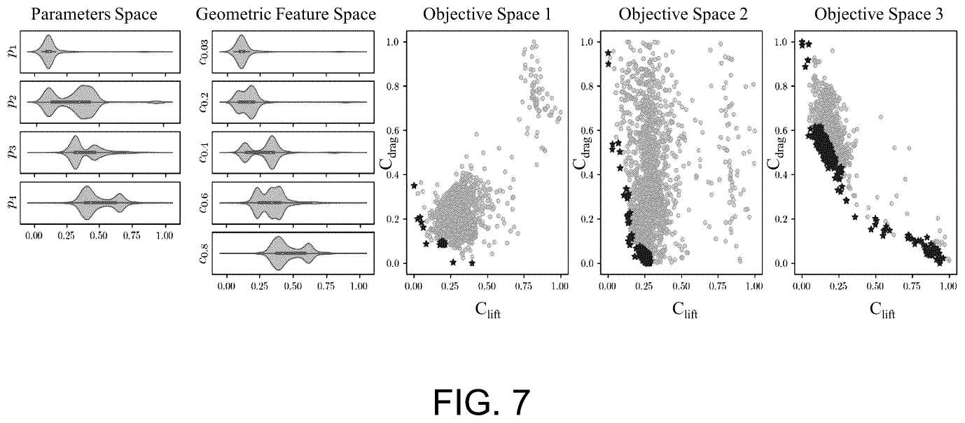

FIG. 7 depicts the first objective space, the second objective space and the third objective space with two dimensions. In the first objective space, the second objective space and the third objective space, data samples of a particular interest are marked.

FIG. 8 depicts a result of the design concept determination process in the airfoil design implementation of an embodiment.

FIG. 8 depicts five description spaces, from left to right are the design parameter space, the geometric parameter space, a first objective space, a second objective space and a third objective space arranged.

The method determines three design concepts, for each of the determined three design concepts, a representative data sample is selected. The selected representative is marked in FIG. 8 using a star. Each determined design concept covers parts of each description space.

FIG. 9 depicts an evaluation of the result of the design concept identification process in the airfoil design implementation of an embodiment.

As shown in FIG. 9, the first design concept comprises 988 design data samples. The second concept includes 362 design data samples. The third concept includes 7 design data samples. The other 1146 design data samples d do not form part of any determined design concept.

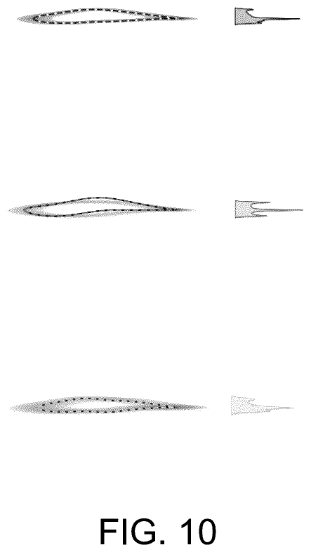

FIG. 10 depicts a selection of representative designs (concept representatives) of the three identified design concepts in the airfoil design implementation of an embodiment. The three design concepts are shown in the upper part of FIG. 10, the center part of FIG. 10 and the lower part of FIG. 10 respectively. For each of the three determined design concepts, a representative data sample is shown with a dashed line. The spatial distribution of the representative data sample for each of the three determined design concepts is shown in the shaded area behind and surrounding the dashed line of the representative data sample. A vertical distribution of the design data samples of each design concept is shown to the left of the design concept.

FIG. 11 shows a simplified flowchart, which depicts method steps of the computer-implemented method for performing a design process by analyzing design data of a physical object.

In step S1, a dataset D including a plurality of design data samples x₁, . . . , x_{N}_{_{D}} of design data is obtained. Each design data sample (data sample) xᵢ represents a design variation of a physical object. Each design data sample xᵢ comprises a plurality of design features f₁, . . . , f_{N}_{_{F}}, wherein each design feature is included in one of a plurality of description spaces.

Method steps S21, S22, and S23 of FIG. 11 discuss the step S2 of FIG. 3 in more detail, which includes determining at least one design concept including a plurality of design data samples x₁, . . . , x_{N}_{_{D}} from the acquired dataset D based on at least a similarity of feature values of the design features f₁, . . . , f_{N}_{_{F}}, wherein each design data sample x₁, . . . , x_{N}_{_{D}} comprises design features in at least two of the description spaces.

The method proceeds with a step S21 of determining plural concept candidates from the obtained dataset D based on at least a similarity of feature values of the design features f₁, . . . , f_{N}_{_{F}}. Each determined concept candidate includes a group of design data samples.

In step S22, a metric Q for the concept candidate configurations is calculated. The calculated metric Q defines a quality of the generated concept candidate configurations and evaluates the design features f₁, . . . , f_{N}_{_{F}} of different description spaces of the plurality of description spaces.

In step S23, the plural concept candidate configurations are evaluated based on the calculated metric Q to generate design concepts.

In step S3, from each generated design concept, one or more representative design data samples for each of the generated design concepts are determined based on at least one selection criterion. Step S3 may include method steps S31, 32, 33 as depicted in in FIG. 3 and discussed with reference to FIG. 3.

The determined representative design data samples for each of the design concepts are then output in step S4.

In step S5, the design process for the physical object based on the output representative design data samples for each of the design concepts is performed.

Subsequently, the physical object may be manufactured based on a resulting design from the performed design process.

The efficiency of this measure renders it particularly useful in the illustrative example of designing physical objects, for example airfoil design as well as on a real-world inspired vehicle design optimization.

The measure also enables performing data compressing of large datasets D to a subset of design data samples representing semantically relevant design concepts of the large dataset D.

Further application areas for the method include recommendation systems for marketplaces. In this particular example of a recommendation system, a dataset D may be obtained from a marketplace where each data sample represents a specific customer, each description space represents a respective affinity of a customer to buy certain products of specific product type, and a design concept represents a group of customers with similar preferences for each product type.

Generally, a design concept is an abstract representation of design solutions that share comparable properties and behavior. Inspecting such design concept facilitates an increase of knowledge about the structure of a specific design problem. Design concepts also allow for the selection of archetypal representatives, which can be used advantageously as prototypes for further processing. Thus, the proposed method is advantageous in engineering processing involving large data sets D comprising a plurality of design data samples x₁, . . . , x_{N}_{_{D}}.

Design concepts can provide valuable insight into the design problem, and the most typical examples within the design concept can be a good basis to start looking for suitable variations of a design of the physical object. Such representative design samples or archetypes share a substantial amount of features with neighboring design candidates and may be used as prototypes in further processing, for example, as initial starting points for subsequent design optimization studies under changed environmental conditions, or case-based reasoning approaches. Prototypes from different design concepts characterize different parts of the search space and therefore create improvement potential in multiple directions for the design of the physical object.

Not only provide design concepts valuable insight into the design problem but they also enable the engineer to derive representative design samples from the dataset D.

A small set of representative design samples from every design concept may reflect some general and/or user provided criteria. For example, the representative design samples may cover and represent the Pareto front of the complete objective space. Alternatively, the representative design samples may represent the complete dataset.

All features described above or features shown in the figures can be combined with each other in any advantageous manner within the scope of the disclosure.

What is claimed is:

1. A computer-implemented method for performing a design process by processing design data of a physical object, the method comprising steps of:
acquiring a dataset D including a plurality of design data samples x₁, . . . , x_{N}_{_{D}} of design data, each design data sample xᵢ representing one design variation of the physical object and comprising a plurality of design features f₁, . . . , f_{N}_{_{F}}, each design feature fᵢ included in at least one of a plurality of description spaces;
determining at least one design concept including a plurality of design data samples x₁, . . . , x_{N}_{_{D}} from the acquired dataset D based on at least a similarity of feature values of the design features f₁, . . . , f_{N}_{_{F}}, wherein each design data sample x₁, . . . , x_{N}_{_{D}} comprises design features in at least two of the description spaces;
calculating a local similarity measure between the at least two description spaces for each design data sample x₁, . . . , x_{N}_{_{D}} included in the determined at least one design concept;
selecting a number of design data samples x₁, . . . , x_{N}_{_{D}} based on the calculated local similarity measure from the plurality of design data samples x₁, . . . , x_{N}_{_{D}} included in the determined at least one design concept as at least one of most representative designs and least representative designs; and
outputting the selected most representative design(s) to an engineering process for further processing, or deleting the least representative design(s) from the design data samples x₁, . . . , x_{N}_{_{D}} of the respective design concept; and
processing at least one of the most representative design data samples x₁, . . . , x_{N}_{_{D}} of the at least one design concept in the engineering process.

2. The computer-implemented method according to claim 1, comprising:
determining relevant description spaces of the plurality of design data samples x₁, . . . , x_{N}_{_{D}} of the at least one design concept; and
calculating the local similarity measure as a correlation between the design data samples x₁, . . . , x_{N}_{_{D}} in different description spaces of the determined relevant description spaces of the plurality of design data samples of the at least one design concept.

3. The computer-implemented method according to claim 1, wherein
the at least two description spaces include at least two of the description space of design specification parameters, geometrical features of the design, design performance parameters of at least one engineering discipline for one set of operation criteria, and an operation mode of the design.

4. The computer-implemented method according to claim 1, wherein
calculating the local similarity measure as local mutual information measure defined by
$$i ( x ; y ) = log \frac{p ( x \vert y )}{p ( x )} ,$$
with the local similarity measure i(x; y), x and y are design data of the design data sample in the respective description spaces and p (x) defines a probability of occurrence of the characteristic data sample x in the first description space, and p (x|y) defines a probability of occurrence of the design data sample x in the first description space when observing the design data sample y in the second description space.

5. The computer-implemented method according to claim 1, wherein
processing the most representative design data samples x₁, . . . , x_{N}_{_{D}} of the at least one design concept in the engineering process includes optimizing the representative design data samples x₁, . . . , x_{N}_{_{D}} with respect to at least one design target using the at least on representative design data sample x₁, . . . , x_{N}_{_{D}} as a starting point for the optimization process.

6. The computer-implemented method according to claim 2, wherein
determining relevant description spaces includes the description spaces design specification subspace and design performance subspace, and
processing the most representative design data samples x₁, . . . , x_{N}_{_{D}} of the at least one design concept in the engineering process includes varying design parameters in the description space of design specification parameters for the at least one representative design for developing design variants of the at least one design concept.

7. The computer-implemented method according to claim 1, wherein
processing the representative design data samples x₁, . . . , x_{N}_{_{D}} of the at least one design concept in the engineering process includes storing the representative design data samples x₁, . . . , x_{N}_{_{D}} of the at least one design concept as a reduced data set of the design concept.

8. The computer-implemented method according to claim 1, wherein
the determined at least one design concept includes the plurality of design data samples fulfilling constraints of
each design data sample x₁, . . . , x_{N}_{_{D}} is included in at maximum one design concept, and
all design features f₁, . . . , f_{N}_{_{F}} of all design data samples x₁, . . . , x_{N}_{_{D}} of the at least one design concept are similar, and
all design data samples x₁, . . . , x_{N}_{_{D}} assigned to the at least one design concept in a joint description space including all description spaces are assigned to the same at least one design concept in each of the description space of the plurality of description spaces.

9. The computer-implemented method according to claim 1, further comprising steps of:
determining at least one design concept including a plurality of design data samples x₁, . . . , x_{N}_{_{D}} from the acquired a dataset D comprising:
determining plural concept candidates from the obtained dataset D based on at least a similarity of feature values of the design features f₁, . . . , f_{N}_{_{F}}, each concept candidate including a group of design data samples, for generating plural concept candidate configurations;
calculating a metric Q for the concept candidate configurations, the calculated metric Q defining a quality of the generated concept candidate configurations, the metric Q evaluating the design features f₁, . . . , f_{N}_{_{F}} of different description spaces of the plurality of description spaces; and
evaluating the plural concept candidate configurations based on the calculated metric Q to generate the at least one design concept.

10. The computer-implemented method according to claim 1, wherein
the similarity of feature values of the design features f₁, . . . , f_{N}_{_{F}} includes at least a similarity in a first description space, in a second description space and in a third description space.

11. The computer-implemented method according to claim 9, wherein
processing the representative design data samples x₁, . . . , x_{N}_{_{D}} of the at least one design concept in the engineering process includes optimizing a design of the physical object based on a fitness function, wherein the fitness function is based on at least one of the calculated metric Q and the selection criterion.

12. The computer-implemented method according to claim 1, wherein
the dataset includes design data samples x₁, . . . , x_{N}_{_{D}} of engineering design data, each data sample xᵢ representing a design of the physical object,
each of the plural description spaces is characterized by a single design feature fᵢ or a group of design features fᵢ, fⱼ, . . . , wherein the group of design features fᵢ, fⱼ, . . . includes one of a set of design data parameters of the physical object, a set of geometrical features of the physical object, a set of performance values of the physical object for defined conditions, and a latent representation of a machine learning approach.

13. The computer-implemented method according to claim 12, wherein the machine learning approach is an auto-encoder or a principal/independent component analysis PCA/ICA.
